(19) United States
(12) Patent Application Publication
(10) Pub. No.: US 2026/0273668 A1
(43) Pub. Date: Sep. 17, 2026

(54) DELAMINATING OF A PHOTOVOLTAIC MODULE

(71) Applicant: NewSouth Innovations Pty Limited, Sydney, New South Wales (AU)

(72) Inventors: Zibo Zhou, Sydney, New South Wales (AU); Rong Deng, Sydney, New South Wales (AU); Martin Andrew Green, Sydney, New South Wales (AU)

(21) Appl. No.: 19/168,258

(22) PCT Filed: Mar. 22, 2024
(86) PCT No.: PCT/AU2024/050267

§ 371 Date: Sep. 23, 2025

(30) Foreign Application Priority Data
Mar. 24, 2023 (AU) 2023900829

(51) Int. Cl. B23K 26/53; B23K 26/082; B23K 101/40

(52) U.S. Cl. CPC B23K 26/53; B23K 26/082; B23K 2101/40

(57) ABSTRACT

A method of delaminating a photovoltaic module is disclosed, the photovoltaic module having a glass layer attached to a silicon layer by an encapsulant layer disposed between the glass layer and the silicon layer, the method comprising: applying a pulsed laser beam through the glass layer of the photovoltaic module to at least partially degenerate the encapsulant layer of the photovoltaic module, the pulsed laser beam having a pulse width and an intensity, wherein the pulse width is selected to be between about 100 femtoseconds and about 10 picoseconds, and the intensity is selected to be greater than 0.1 terawatts per square centimetre, such that the encapsulant layer is at least partially degenerated by the pulsed laser beam without substantially increasing a resting temperature of the encapsulant layer, and separating at least one of the glass layer and the silicon layer from the encapsulant layer of the photovoltaic module.

### CROSS-REFERENCE TO RELATED APPLICATIONS

The present application claims priority to Australian provisional patent application no. 2023900829 filed 24 Mar. 2024, the entire content of which is incorporated herein by reference.

### TECHNICAL FIELD

The present disclosure relates, generally, to delamination of photovoltaic modules.

### BACKGROUND

With a continued worldwide focus on renewable energy sources, globally installed photovoltaic modules are anticipated to rise 11-fold in the next 30 years. This increased usage of photovoltaic modules necessarily leads to an increase in photovoltaic waste as the modules reach their end of life, with crystalline silicon photovoltaic modules expected to make up the majority of photovoltaic module waste for the foreseeable future.

Crystalline silicon photovoltaic modules typically comprise: glass, aluminum frames, EVA (ethylene-vinyl acetate) copolymer transparent encapsulating layers, solar cells, junction boxes (j-box), polymer backsheets and other accessories such as cabling, with each of these components presenting different recycling challenges.

Photovoltaic modules typically have a lifespan of 25-30 years, although their end of life is contingent on a particular module's performance and can occur sooner for a number of reasons. For example, if modules are defective or significantly degraded and repair is not feasible, then end of life may occur many years prior to the module's expected lifetime.

A benefit of photovoltaic module recycling arises from the re-use potential of recovered materials, which can offset the economic costs and environmental impacts of raw material production. In addition, crystalline silicon photovoltaic modules contain a number of valuable metals such as aluminum, copper and silver, which have finite reserves and therefore the availability of these metals may become depleted in the future.

While the environmental benefits of photovoltaic module recycling are clear, the recycling process it is often not economically feasible due to high equipment and processing costs, difficulties in achieving adequate separation of photovoltaic module components, insufficient recovery of valuable components, or recovered component fractions being insufficiently pure so as not to justify the investment and operating costs. In addition, known recycling techniques, while achieving a separation of components, can involve hazardous chemicals or require high energy consumption and therefore the environmental benefits of recycling the photovoltaic modules may be outweighed by the environmental costs of performing the recycling. In some methods, materials recovered from the recycling process are not in suitable form for re-use; for example, the recovered materials may be in a shredded form as opposed to being recovered as a large or whole portion or layer of material. Often, waste photovoltaic modules are simply disposed of as landfill.

There are several approaches to recycling photovoltaic modules. Typically, such methods have an initial step of mechanically separating or delaminating the frame and junction box (j-box) from a photovoltaic sandwich structure. In crystalline modules, this sandwich structure is typically made up of one or more solar cells including a silicon layer that includes metallization on one or more of its surfaces (e.g. metal fingers, metal busbars, metal contacts etc.), the silicon layer being sandwiched between encapsulant layers, such as ethylene-vinyl acetate (EVA) layers, which adhere the silicon layer to a front glass layer and either a glass or polymer backsheet layer.

The layers of the sandwich structure can be separated, for example, using thermal or chemical techniques which target the EVA. Thermal treatments involve decomposing the EVA layer at high temperatures of approximately 500° C. using either pyrolysis or combustion. This allows for separation of glass, silicon and backsheet layers. However, achieving the high temperatures required for thermal separation can be energy-intensive and mechanical pressure from decomposing gases can cause the silicon layer to crack, thereby reducing the value of recovered silicon layer materials compared to the recovery of the whole silicon layer.

Separation of the glass, silicon and backsheet layers can also be achieved using chemical solvents to dissolve the encapsulant layer. Once separated, the solar cells can be treated with specific acids or hydroxides to individually remove internal metals such as copper and silver. Chemical recycling techniques have the potential to separate high-quality metals, however they often require the use of toxic chemicals which must be appropriately disposed of after a single use, thereby negatively impacting the environment.

The European “Full Recovery End of Life Photovoltaic” (FRELP) project is a targeted recovery process for crystalline photovoltaic modules, able to achieve high-quality material yields using a multi-stepped approach. After removal of the aluminum frame, j-box and cabling, glass is separated from the photovoltaic sandwich structure using a high-frequency cutting knife with an elevated temperature furnace. Optical separation is then used to separate glass into similarly sized pieces and remove contaminants. The remaining silicon layer is cut into small pieces and incinerated to produce energy and ash containing silicon and various metals and the ash sieved to separate metal connectors originally contained in the laminate. Acid leaching is used to dissolve remaining metals and the remaining residue can be filtered to recover the silicon fraction and electrolysis used to yield the copper and silicon from the metallic oxides within the remaining solution.

The FRELP process provides a good recovery of material, allowing for over 95% of the glass, aluminum, silver and silicon to be recovered. However, the FRELP process requires a high throughput of at least approximately 7,000 tonnes/year to be economically viable, with reductions in the quantities of valuable materials (such as silver and silicon) used in newer modules posing a further economic challenge for the FRELP and other processes. Also, the ash, organic solvent, and undecomposed heavy carbon gases produced form the FRELP process must also be disposed of which is damaging to the environment.

Further, the FRELP process is a time intensive multi-stepped approach and does not separate the glass and silicon cell components as whole layers, thereby reducing the value of the recovered materials. In addition, the high-frequency cutting knife and furnace used in the separation step of the FRELP process are designed for a fixed size of photovoltaic module, thereby reducing the versatility of the separation step to separate or delaminate photovoltaic modules of different shapes and sizes.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY

In a first aspect of the present disclosure, there is provided a method of delaminating a photovoltaic module, the photovoltaic module having a glass layer attached to a silicon layer by an encapsulant layer disposed between the glass layer and the silicon layer, the method comprising: applying a pulsed laser beam through the glass layer of the photovoltaic module to at least partially degenerate the encapsulant layer of the photovoltaic module, the pulsed laser beam having a pulse width and an intensity, wherein the pulse width is selected to be between about 100 femtoseconds and about 10 picoseconds, and the intensity is selected to be greater than 0.1 terawatts per square centimetre, such that the encapsulant layer is at least partially degenerated by the pulsed laser beam without substantially increasing a resting temperature of the encapsulant layer; and separating at least one of the glass layer and the silicon layer from the encapsulant layer of the photovoltaic module.

The applying of the pulsed laser beam may degenerate substantially only one or more portions of the encapsulant layer that are proximate the glass layer and/or one or more portions of the encapsulant layer that are proximate the silicon layer. The applying of the pulsed laser beam may degenerate one or more portions of the encapsulant layer proximate the glass layer simultaneously with one or more portions of the encapsulant layer proximate the silicon layer. Other portions of the encapsulant layer, such as one or more portions that are further from the glass layer and/or silicon layer, may therefore not be degenerated by the pulsed laser beam in some embodiments.

The glass layer may comprise an operatively front facing glass layer, and the applying the pulsed laser beam through the glass layer may comprise applying the pulsed laser beam through the operatively front facing glass layer. The glass layer may comprise a glass backsheet, and the applying the pulsed laser beam through the glass layer may comprise applying the pulsed laser beam through the glass backsheet.

The method described above may further comprise scanning the pulsed laser beam along the glass layer. The scanning of the pulsed laser beam may comprise scanning the pulsed laser beam along a path comprising a series of spaced, substantially straight lines. The scanning of the pulsed laser beam may comprise applying pulses of the pulsed laser beam through a first discrete portion of the glass layer, and subsequently applying pulses of the pulsed laser beam through a different, second discrete portion of the glass layer. The first discrete portion may overlap, for example, between about 10% and about 90% of the second discrete portion, or between about 30% and about 60% of the second discrete portion, or between about 45% and about 55% of the second discrete portion. The scanning the pulsed laser beam may comprise applying pulses of the pulsed laser beam subsequently through further discrete portions of the glass layer, wherein each discrete portion may overlap, for example, between about 10% and about 90%, or between about 30% and about 60%, or between about 45% and about 55%, of at least one other discrete portion.

The separating at least one of the glass layer and the silicon layer from the encapsulant layer may comprise separating at least one of the glass layer and the silicon layer as a single piece of material. The separating at least one of the glass layer and the silicon layer from the encapsulant layer may comprise peeling the encapsulant layer away from at least one of the glass layer and the silicon layer or peeling at least one of the glass layer and the silicon layer away from the encapsulant layer. The separating at least one of the glass layer and the silicon layer from the encapsulant layer may comprise separating both the glass layer and the silicon layer from the encapsulant layer.

A wavelength of the pulsed laser beam may be selected to be, for example, between about 300 nanometres and about 1100 nanometres, or between about 300 nanometres and about 800 nanometres, or between about 400 nanometres and about 600 nanometres. A fluence of the pulsed laser beam may be selected to be, for example, between about 1 joule per square centimetre and about 10 joules per square centimetre, or between about 3 joules per square centimetre and about 8 joules per square centimetre, or between about 5 joules per square centimetre and about 7 joules per square centimetre. The intensity of the pulsed laser beam may be selected to be, for example, between about 0.1 terawatts per square centimetre and about 50 terawatts per square centimetre, or between about 0.5 terawatts per square centimetre and about 10 terawatts per square centimetre, or between about 1 terawatt per square centimetre and about 5 terawatts per square centimetre. A deactivation period of the pulsed laser beam between pulses may be selected to be, for example, between about 1 microsecond and about 10 microseconds, or between about 3 microseconds and about 8 microseconds. A power of the pulsed laser beam may be selected to be, for example, between about 0.5 watts and about 3000 watts, or between about 0.5 watts and about 1000 watts, or between about 0.5 watts and about 200 watts, or between about 0.5 watts and about 100 watts, or between about 0.5 watts and about 50 watts, or between about 0.5 watts and about 10 watts, or between about 0.5 watts and about 1 watt, or to be over about 0.5 watts, or over about 1 watt, or over about 10 watts, or over about 100 watts, or over about 200 watts, or over about 1000 watts, or over about 2000 watts.

In a second aspect of the present disclosure, there is provided a method of delaminating a photovoltaic module, the photovoltaic module having a backsheet attached to a silicon layer by an encapsulant layer disposed between the backsheet and the silicon layer, the method comprising: separating the backsheet from the encapsulant layer; applying a pulsed laser beam to the encapsulant layer of the photovoltaic module to at least partially degenerate the encapsulant layer of the photovoltaic module, the pulsed laser beam having a pulse width and an intensity, wherein the pulse width is selected to be between about 100 femtoseconds and about 10 picoseconds, and the intensity is selected to be greater than 0.1 terawatts per square centimetre, such that the encapsulant layer is at least partially degenerated by the pulsed laser beam without substantially increasing a resting temperature of the encapsulant layer; and separating the silicon layer from the encapsulant layer of the photovoltaic module.

It will be understood that the method described in the second aspect may include any one or more of the applicable features described in respect of the first aspect.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of example only with reference to the accompanying drawings in which:

FIG. 1 shows a flowchart of an embodiment of a method of delaminating a photovoltaic module comprising applying a pulsed laser beam through a glass layer;

FIG. 2 shows a schematic of a cross section of a sandwich structure of a photovoltaic module having a glass layer attached to a silicon layer by an encapsulant layer disposed between the glass layer and the silicon layer;

FIG. 3 shows a schematic of the cross section of the sandwich structure shown in FIG. 2 while an embodiment of the method of delaminating a photovoltaic module is performed;

FIG. 4 shows the schematic of the cross section of the sandwich structure shown in FIG. 2 while another embodiment of the method of delaminating a photovoltaic module is performed;

FIG. 5 shows the schematic of the cross section of the sandwich structure shown in FIG. 2 while another embodiment of the method of delaminating a photovoltaic module is performed;

FIG. 6 shows the schematic of the cross section of the sandwich structure shown in FIG. 2 while another embodiment of the method of delaminating a photovoltaic module is performed;

FIG. 7 shows a schematic of discrete portions of the glass layer through which the pulsed laser beam is applied while the pulsed laser beam is scanned along a glass layer to perform the method shown in one or more of FIGS. 1 and 3-6;

FIG. 8 shows a schematic of spaced discrete portions of the glass layer through which the pulsed laser beam is applied while the pulsed laser beam is scanned along a glass layer to perform the method shown in one or more of FIGS. 1 and 3-6;

FIG. 9 shows a flowchart of another embodiment of a method of delaminating a photovoltaic module;

FIG. 10 shows a photograph of a photovoltaic sandwich structure following applying the pulsed laser beam of the method shown in FIG. 1;

FIGS. 11a and 11b each show a photograph of a separated photovoltaic sandwich structure following applying the method shown in FIG. 1;

FIG. 12 shows a cross section photograph of a glass-glass photovoltaic sandwich structure under a microscope following applying the pulsed laser beam of the method shown in FIG. 1; and

FIG. 13 shows a photograph of a sandwich structure following applying the pulsed laser beam of the method shown in FIG. 1 at increasing laser power.

### DESCRIPTION OF EMBODIMENTS

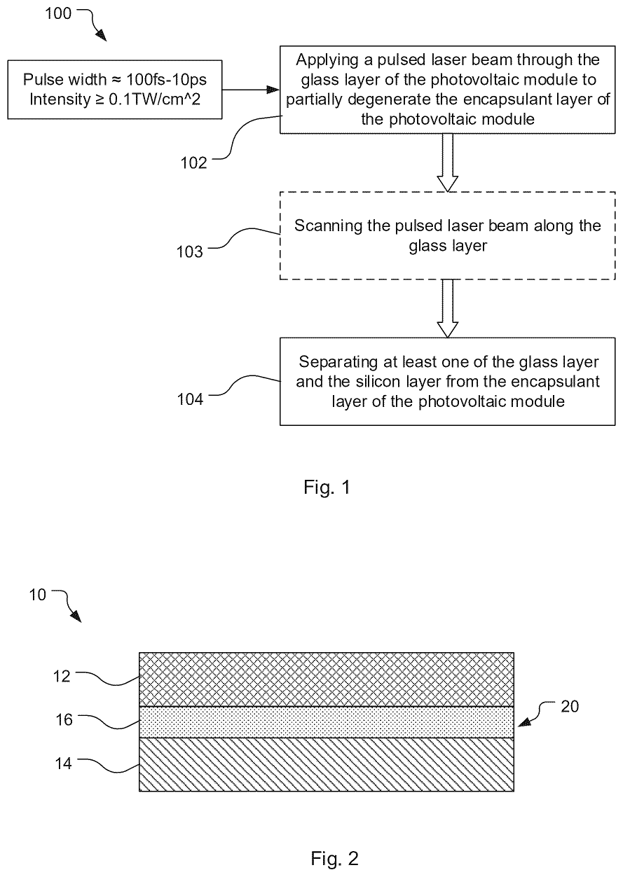

With reference to FIG. 1, a method 100 of delaminating a photovoltaic module 10 according to an embodiment of the present disclosure is disclosed. With further reference to FIG. 2, the photovoltaic module 10 has a glass layer 12 attached to a silicon layer 14 by an encapsulant layer 16 disposed between the glass layer 12 and the silicon layer 14. The method 100 comprises applying 102 a pulsed laser beam 18 through the glass layer 12 of the photovoltaic module 10 to at least partially degenerate the encapsulant layer 16 of the photovoltaic module 10. The pulsed laser beam 18 has a pulse width and an intensity, wherein the pulse width is selected to be between about 100 femtoseconds and about 10 picoseconds, and the intensity is selected to be greater than 0.1 terawatts per square centimetre, such that the encapsulant layer 16 is at least partially degenerated by the pulsed laser beam 18 without substantially increasing a resting temperature of the encapsulant layer 16. The method 100 further comprises separating 104 at least one of the glass layer 12 and the silicon layer 14 from the encapsulant layer 16 of the photovoltaic module 10.

The glass layer 12, the silicon layer 14 and the encapsulant layer 16 together form a sandwich structure 20 of the photovoltaic module 10 as illustrated in FIG. 2. The silicon layer 14 is representative of a solar cell and will be referred to as a silicon layer in the present disclosure, although it may include additional layers or components such as metallization (e.g., metal conductors, metal busbars and metal contacts). The encapsulant layer 16 may be formed from any suitable polymer material, such as ethyl vinyl acetate (EVA), polyolefin encapsulant (POE), polyvinyl butyral, silicones, thermoplastics, and the like. It will be understood that the silicon layer 14 may be formed from a single layer as shown in the drawings or from a plurality of adjacent or spaced layers.

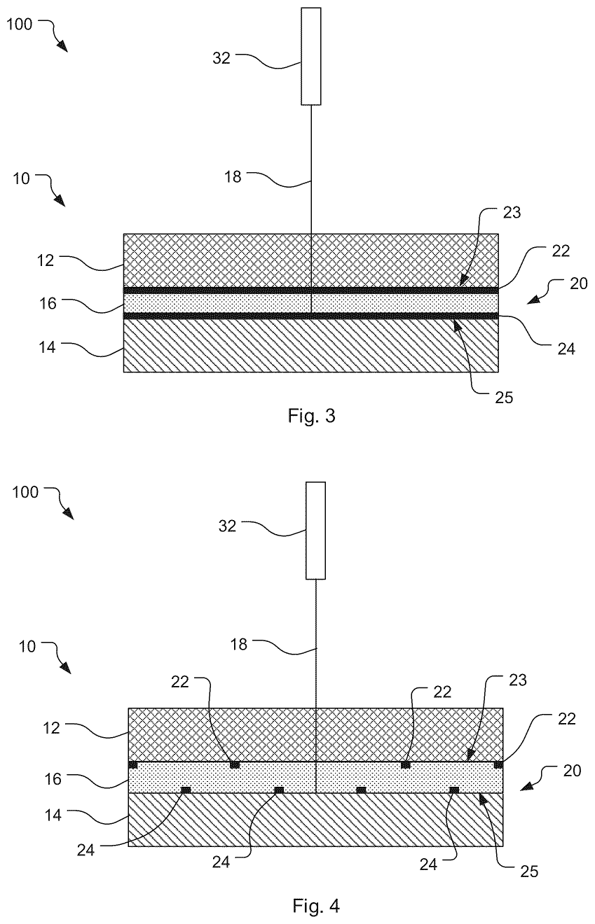

In some embodiments, the applying 102 of the pulsed laser beam 18 degenerates substantially only one or more portions 22 of the encapsulant layer 16 that are proximate the glass layer 12 and/or one or more portions 24 of the encapsulant layer 16 that are proximate the silicon layer 14. In some embodiments, the applying 102 of the pulsed laser beam 18 degenerates the one or more portions 22 of the encapsulant layer 16 that are proximate the glass layer 12 simultaneously with the one or more portions 24 of the encapsulant layer 16 that are proximate the silicon layer 14. FIGS. 3-6 illustrate these various embodiments of the method 100.

FIG. 3 shows an embodiment in which the pulsed laser beam 18 is applied through the glass layer 12, and travels through the encapsulant layer 16 until the pulsed laser beam 18 is blocked by the silicon layer 14. In this embodiment, a portion 22 of the encapsulant layer 16 proximate the glass layer 12 and a portion 24 of the encapsulant layer 16 proximate the silicon layer 14 are degenerated as a result of the applied pulsed laser beam 18. In other words, the portions 22, 24 of the encapsulant layer 16 at the glass layer/encapsulant layer interface 23 and at the encapsulant layer/silicon layer interface 25, respectively, are degenerated. A central area (bulk) of the encapsulant layer 16 located between these portions 22, 24 may not be degenerated. The degeneration of the encapsulant layer 16 is achieved through scanning the pulsed laser beam across the glass layer 12 (generally in a direction parallel to the plane of the glass layer 12) and the operating parameters of the pulsed laser beam 18 are selected such that the probability of the degeneration of the encapsulant layer 16 at the interfaces 23, 25 by cold ablation is greatly increased. These mechanisms are discussed in greater detail below.

FIG. 4 shows an alternative embodiment in which the pulsed laser beam 18 is again applied through the glass layer 12, and travels through the encapsulant layer 16 until the pulsed laser beam 18 is blocked by the silicon layer 14. In this embodiment, a plurality of portions 22 of the encapsulant layer 16 that are proximate the glass layer 12 and a plurality of portions 24 of the encapsulant layer 16 that are proximate the silicon layer 14 are degenerated as a result of the applied pulsed laser beam 18. In other words, portions 22 of the encapsulant layer 16 at the glass layer/encapsulant layer interface 23 and portions 24 at the encapsulant layer/silicon layer interface 25 are degenerated. Areas of the encapsulant layer 16 that are between the portions 22 of the encapsulant layer 16 at the glass/encapsulant interface 23, or areas of the encapsulant layer 16 that are between the portions 24 of the encapsulant layer 16 at the encapsulant layer/silicon layer interface 25, or a central area (bulk) of the encapsulant layer 16 located between these portions 22, 24, may not be degenerated. The at least partial degeneration of the encapsulant layer 16 is achieved through scanning the pulsed laser beam across the glass layer 12 (generally in a direction parallel to the plane of the glass layer 12). The operating parameters of the pulsed laser beam 18 are selected such that degeneration of the encapsulant layer 16 at the interfaces 23, 25 occurs at spaced portions 22, 24 in order to provide enough degeneration of the encapsulant layer 16 for the separating 104, while increasing the speed of the applying 102 of the pulsed laser beam 18 by not requiring the entirety of one or both of the interface regions 23, 25 of the encapsulant layer 16 to be degenerated. Again, cold ablation may also be achieved.

In one example, the degeneration of the encapsulant layer 16 as shown in FIG. 4 may be provided by scanning the pulsed laser beam 18 across the glass layer 12 at spaced portions. For some encapsulant materials, such as EVA, gas bubbles may begin to form between the glass layer 12 and the encapsulant layer 16, and/or between the silicon layer 14 and the encapsulant layer 16, beneath the portions of the glass layer 12 through which the pulsed laser beam 18 is applied. The gas bubbles may expand in some embodiments, thereby causing further degeneration of the encapsulant layer 16 at the interfaces 23, 25 corresponding with a maximum dimension of the gas bubbles. The maximum dimension of the gas bubbles increase with increasing power of the pulsed laser beam 18. Thus, expanding gas bubbles may cause the pattern of degeneration shown in FIG. 4. Further reference may also be made to the Example below discussed with reference to FIG. 13.

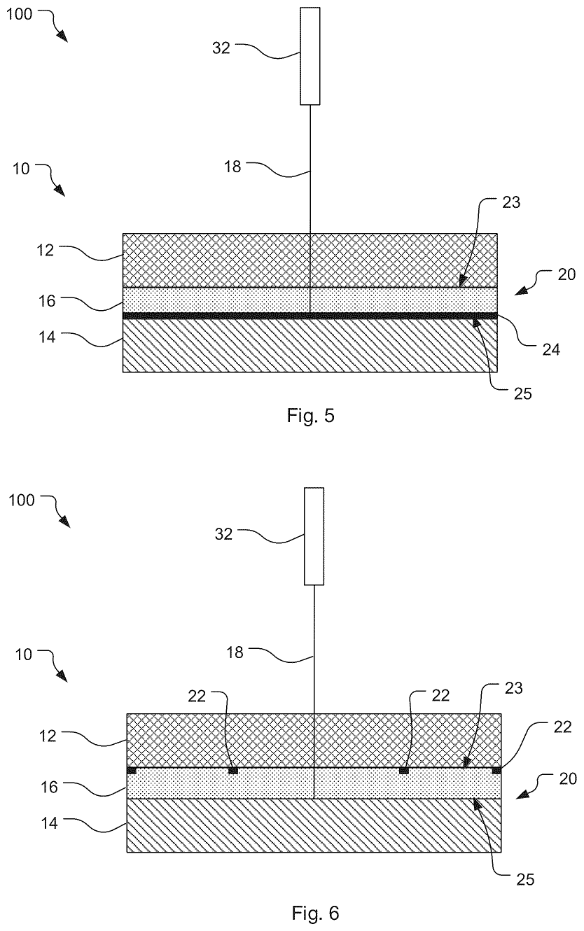

FIG. 5 shows an embodiment in which the pulsed laser beam 18 is applied through the glass layer 12, and travels through the encapsulant layer 16 until the pulsed laser beam 18 is blocked by the silicon layer 14. In this embodiment, only one portion 24 of the encapsulant layer 16 proximate the silicon layer 14 is degenerated as a result of the applied pulsed laser beam 18. In other words, the portion 24 of the encapsulant layer 16 at the encapsulant layer/silicon layer interface 25 is degenerated only. The degeneration of the encapsulant layer 16 is achieved through scanning the pulsed laser beam across the glass layer 12 (generally in a direction parallel to the plane of the glass layer 12) and the operating parameters of the pulsed laser beam 18 are selected such that degeneration of the encapsulant layer 16 at only the encapsulant layer/silicon layer interface 25 occurs. This may allow only the silicon layer 14 to be separated from the encapsulant layer 16. It will be understood that only one portion 22 at the glass layer/encapsulant layer interface 23 of the encapsulant layer 16 may be degenerated in other embodiments, and this may allow only the glass layer 12 to be separated from the encapsulant layer 16. Again, cold ablation may also be achieved. In one example, the degeneration of the encapsulant layer 16 as shown in FIG. 5 may be provided by applying 102 the pulsed laser beam 18 with a longer wavelength of between about 1000 and about 1100 nanometres in order to increase the penetration of the pulsed laser beam 18 through the glass layer 12 such that the pulsed laser beam 18 is effective substantially at the encapsulant layer/silicon layer interface 25.

FIG. 6 shows an embodiment in which the pulsed laser beam 18 is applied through the glass layer 12, and travels through the encapsulant layer 16 until the pulsed laser beam 18 is blocked by the silicon layer 14. In this embodiment, only a plurality of portions 22 of the encapsulant layer 16 proximate the glass layer 12 are degenerated as a result of the applied pulsed laser beam 18. In other words, the portions 22 of the encapsulant layer 16 at the glass layer/encapsulant layer interface 23 are degenerated. It will be understood that only a plurality of portions 24 of the encapsulant layer 16 proximate the silicon layer 14 may be degenerated in other embodiments. This degeneration of the encapsulant layer 16 is achieved by scanning the pulsed laser beam across the glass layer 12 (generally in a direction parallel to the plane of the glass layer 12) and the operating parameters of the pulsed laser beam 18 are selected such that degeneration of the encapsulant layer 16 occurs, at only the glass layer/encapsulant layer interface 23, at spaced portions 22, in order to provide enough degeneration of the encapsulant layer 16 for the separating 104 the glass layer 12 from the encapsulant layer 16, while increasing the speed of the applying 102 of the pulsed laser beam 18 by not requiring the entire interface 23 of the encapsulant layer 16 to be degenerated. Again, cold ablation may also be achieved. In one example, the degeneration of the encapsulant layer 16 as shown in FIG. 6 may be provided by applying 102 the pulsed laser beam 18 with a shorter wavelength of between about 300 and about 400 nanometres in order to reduce the penetration of the pulsed laser beam 18 through the glass layer 12 such that the pulsed laser beam 18 is effective substantially at the glass layer/encapsulant layer interface 23.

In some embodiments, the glass layer 12 comprises an operatively front facing glass layer. In other words, the glass layer 12 may be configured to receive direct solar energy therethrough. In other embodiments, the glass layer 12 comprises a glass backsheet, for example, as a part of a bifacial glass-glass photovoltaic module 10. In other embodiments, the backsheet may be formed of a different transparent material, such as a polymer. It will be understood that the method 100 may be performed by instead applying the pulsed laser beam 18 through the transparent backsheet in other embodiments.

The separating 104 at least one of the glass layer 12 and the silicon layer 14 from the encapsulant layer 16 may comprise separating at least one of the glass layer 12 and the silicon layer 14 as a single piece of material. For example, one or both of the glass layer 12 and the silicon layer 14 may be separated from the encapsulant layer 16 as a whole layer without cracking or otherwise damaging the glass and/or silicon material during the process. In some embodiments, the separating 104 may comprise a mechanical process, such as peeling the encapsulant layer 16 away from at least one of the glass layer 12 and the silicon layer 14 either manually or using machinery. The separating 104 may also include running a knife or sharp object along one or both of the interfaces 23, 25 to remove any residual encapsulant material to assist with separating at least one of the glass layer 12 and the silicon layer 14 from the encapsulant layer 16.

It will be understood that following the separating 104, residue from the encapsulant layer 16 may be present on the glass layer 12 and/or the silicon layer 14. In these cases, the residue of the encapsulant layer 16 may be removed from the glass layer 12 and/or the silicon layer 14 in a further process. In some embodiments, at least about 50%, at least about 60%, at least about 70% at least about 80%, at least about 90%, at least about 95%, or at least about 99% of the total volume or weight of the encapsulant layer 16 is separated from at least one of the glass layer 12 and the silicon layer 14.

The pulse width of each pulse of the pulsed laser beam 18 is defined as a measure of the elapsed time between a leading edge and a trailing edge of a pulse signal. In some embodiments, the intensity of the pulsed laser beam is selected to be, for example, between about 0.1 terawatts per square centimetre and about 50 terawatts per square centimetre, or between about 0.5 terawatts per square centimetre and about 10 terawatts per square centimetre, or between about 1 terawatt per square centimetre and about 5 terawatts per square centimetre. In some embodiments, a wavelength of the pulsed laser beam 18 is selected to be, for example, between about 300 nanometres and about 1100 nanometres, or between about 300 nanometres and about 800 nanometres, or between about 400 nanometres and about 600 nanometres. The wavelength of the pulsed laser beam 18 is selected in order to allow the pulsed laser beam 18 to penetrate the glass layer 12 and to not be substantially absorbed by the silicon layer 14 after penetrating the encapsulant layer 16 in order to avoid substantially increasing the temperature of, and thereby causing damage to, the silicon layer 14.

In some embodiments, a fluence of the pulsed laser beam 18 is selected to be, for example, between about 1 joule per square centimetre and about 10 joules per square centimetre, or between about 3 joules per square centimetre and about 8 joules per square centimetre, or between about 5 joules per square centimetre and about 7 joules per square centimetre. In some embodiments, a deactivation period of the pulsed laser beam 18 between pulses is selected to be, for example, between about 1 microsecond and about 10 microseconds, or between about 3 microseconds and about 8 microseconds, the deactivation period being defined as a measure of the elapsed time between the end of one pulse and the start of the next pulse. In some embodiments, a pulse repetition rate of the pulsed laser beam 18 is, for example, between about 100 kilohertz and about 1 megahertz, the pulse repetition rate being defined as the number of pulses of the pulsed laser beam 18 transmitted in 1 second. In some embodiments, a power of the pulsed laser beam is selected to be, for example, between about 0.5 watts and about 3000 watts, or between about 50 watts and about 1000 watts, or between about 50 watts and about 200 watts, or between about 50 watts and about 100 watts, or between about 0.5 watts and about 50 watts, or between about 0.5 watts and about 10 watts, or between about 0.5 watts and about 1 watt, or to be over about 0.5 watts, or over about 1 watt, or over about 10 watts, or over about 100 watts, or over about 200 watts, or over about 1000 watts, or over about 2000 watts. It will be understood that increasing the power of the pulsed laser beam 18 increases the probability of the degeneration of the encapsulant layer 16 as discussed in more detail below.

The mechanism by which at least part of the encapsulant layer 16 is degenerated is non-thermal ablation or cold ablation. Cold ablation is different from photothermal ablation in that removal or ablation of material occurs without the generation (or without requiring the generation) of heat, thereby being considered a cold process. In this way, at least part of the encapsulant layer 16 is degenerated or ablated or removed without substantially increasing the resting temperature of the encapsulant layer 16.

Without intending to be bound by scientific theory, cold ablation typically involves the bond breaking of material at the atomic level, in this case the encapsulant layer 16, due to multiphoton absorption in which two or more photons are simultaneously absorbed by a molecule, which excites the molecule from a ground state to an excited state, thereby breaking the bond of the molecule. The bond of the molecule is able to be broken as a cold process due to the thermal relaxation time of the material, in this case the encapsulant layer 16, being longer than the pulse width of the pulsed laser beam 18. The thermal relaxation time of a material represents the length of time taken for kinetic or thermal energy of electrons that have absorbed laser energy to be transferred to the surrounding lattice of the material. Thus, if the pulse width of the pulsed laser beam 18 is shorter than the thermal relaxation time of the material, in this case the encapsulant layer 16, the multiphoton absorption is thermally confined and therefore the bond breaking of the material is completed before thermal energy is able to be transferred to the surrounding material lattice.

The portions 22, 24 of the encapsulant layer 16 proximate both the glass layer 12 and the silicon layer 14, respectively, being degenerated or removed or ablated simultaneously or at similar times during the applying 102 of the pulsed laser beam 18, is a surprising result. Again without intending to be bound by scientific theory, the reason for this result is that the molecules of the encapsulant layer 16 at the interfaces 23, 25 of the encapsulant layer 16, i.e. at the boundary or periphery of the encapsulant layer 16, are less confined in the material lattice than molecules within the central area or bulk of the encapsulant layer 16, thereby requiring less bonds to be broken by cold ablation at the interfaces 23, 25 to cause removal of the encapsulant material. However, it will be understood that, in some embodiments, some degeneration of the bulk of the encapsulant layer 16 occurs during the applying 102 of the pulsed laser beam 18, and that in other embodiments, little to no degeneration of the bulk of the encapsulant layer 16 occurs during the applying 102 of the pulsed laser beam 18.

The probability of multiphoton absorption occurring is proportional to the square of light intensity, therefore the fluence range of the pulsed laser beam 18 is able to remain lower than the fluence ranges used for photothermal ablation, while the intensity range of the pulsed laser beam 18 is above the intensity ranges used in photothermal ablation in order to increase the probability of multiphoton absorption occurring. Since multiphoton absorption is probability-based, the various forms of degeneration shown in FIGS. 3-6, as well as many other forms of degeneration, are possible by the applying 102 of the pulsed laser beam 18. Thus, the selected pulse width range of the pulsed laser beam 18 allows for multiphoton absorption to occur and the selected intensity range increases the probability of multiphoton absorption occurring. In particular, the intensity ranges of the pulsed laser beam 18 disclosed herein are more likely to allow for two photon absorption to occur.

The intensity of the pulsed laser beam 18 reduces or decays due to the multiphoton absorption as the pulsed laser beam 18 penetrates further into the encapsulant layer 16. Therefore, referring to FIGS. 3-6, the intensity of the pulsed laser beam 18 striking the glass layer/encapsulant layer interface 23 is greater than the intensity of the pulsed laser beam 18 striking the encapsulant layer/silicon layer interface 25. Therefore, in order for the portions 22, 24 of the encapsulant layer 16 proximate both the glass layer 12 and the silicon layer 14, respectively, to be degenerated or removed or ablated, the intensity of the pulsed laser beam 18 may be sufficiently high to account for intensity decay while still enabling cold ablation to occur at the portion 24 of the encapsulant layer 16 proximate the silicon layer 16.

It will be appreciated that during the application of the pulsed laser beam 18, a small amount of photothermal ablation may occur, however, this may only increase the resting temperature of the encapsulant layer 16 by, for example, less than about 20° C., less than about 15° C., less than about 10° C., less than about 9° C., less than about 8° C., less than about 7° C., less than about 6° C., less than about 5° C., less than about 4° C., less than about 3° C., less than about 2° C., less than about 1° C., less than about 0.5° C., less than about 0.1° C., less than about 0.01° C., or less than about 0.001° C. If no photothermal ablation occurs during the application of the pulsed laser beam 18, the resting temperature of the encapsulant layer 16 will not increase at all. It will be understood that the temperature increase ranges of the encapsulant layer 16 provided above fall within the definition of “without substantially increasing the resting temperature” of the encapsulant layer 16. It will also be understood that the resting temperature of the encapsulant layer 16 is the temperature of the encapsulant layer 16 within the general environment in which it is being processed and without any separate heating processes applied to the photovoltaic module 10 in order to heat the encapsulant layer 16.

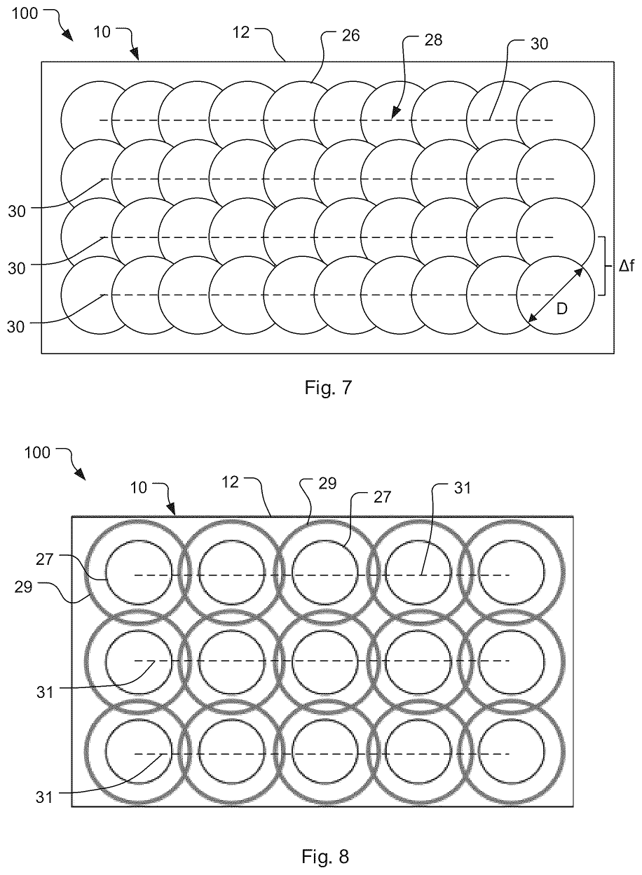

In some embodiments, the method 100 comprises scanning 103 the pulsed laser beam 18 across the glass layer 12. FIG. 7 shows a schematic of discrete portions 26 of the glass layer 12 through which the pulsed laser beam 18 is applied while the pulsed laser beam 18 is scanned across the glass layer 12 (generally in a direction parallel to the plane of the glass layer 12). As shown in FIG. 7, the scanning 103 of the pulsed laser beam 18 comprises scanning the pulsed laser beam 18 along a path 28 comprising a series of spaced, substantially straight lines 30.

It will be understood that the path 28 along which the pulsed laser beam 18 is scanned may be any suitable pattern, such as a raster, zig-zag, spiral, triangular, or rectangular pattern, that the path 28 may be discontinuous, and that the path 28 may comprise curved lines or a combination of straight and curved lines in other embodiments. It will also be understood that the path 28 may follow, or be offset from, a periphery of the glass layer 12 with application to, for example, smaller photovoltaic modules 10 for which degeneration of the encapsulant layer 16 along the periphery of the interfaces 23, 25 is sufficient to enable the separating 104 at least one of the glass layer 12 and the silicon layer 14 from the encapsulant layer 16.

FIG. 7 also illustrates that the scanning 103 the pulsed laser beam 18 comprises applying pulses of the pulsed laser beam 18 through discrete portions 26 of the glass layer 12 such that each discrete portion 26 overlaps between about 10% and about 90% of at least one other discrete portion 26, or between about 30% and about 60% of at least one other discrete portion 26, or between about 45% and about 55% of at least one other discrete portion 26. The discrete portions 26 are represented by circles which define a diameter D of the pulsed laser beam 18 and the proportion of the overlap between pulses along a line 30, i.e. the overlap of the discrete portions 26 along a single straight line 30, is a function of the diameter D, a scanning velocity of the pulsed laser beam 18, and the pulse width of the pulsed laser beam 18. The proportion of the overlap between pulses on two different straight lines 30 is a function of the diameter D and a spacing Δf between each adjacent line 30. The diameter D may be between about 0.1 microns and about 1000 microns, or between about 10 microns and about 100 microns, or between about 20 microns and about 30 microns. The scanning velocity may be up to 100 metres per second and, more particularly, between about 0.5 metres per second and about 10 metres per second. The spacing Δf may be between about 0.1 microns and about 1000 microns.

It will be understood that each discrete portion 26 may overlap more than one other discrete portion 26 on the same line 30, and that each discrete portion 26 of a line 30 may overlap more than one other discrete portion 26 on an adjacent line 30 and may also overlap one or more discrete portions 26 of another adjacent line 30. It will also be understood that in some embodiments, the overlap proportion may be 0%, i.e. the discrete portions 26 may be spaced from each other. In general, higher overlap proportions allow for more of the encapsulant layer 16 to be degenerated or removed or ablated, and lower overlap proportions allow for the applying 102 of the pulsed laser beam 18 to be completed in a shorter time frame. Therefore, a lower overlap proportion or no overlap may be selected in order to increase manufacturing efficiency and throughput in some embodiments.

FIG. 8 shows a schematic of an embodiment of the scanning 103 being implemented through the glass layer 12 at spaced discrete portions 27 along spaced, straight lines 31. In the illustrated embodiment, gas has been produced at each of the spaced discrete portions 27 as a result of the degeneration of the encapsulant layer 16 at one or both of the interfaces 23, 25. The gas generated at each spaced discrete portion 27 expands outwardly throughout one or both of the interfaces 23, 25. The gas also expands towards the glass layer 12 in the case of the glass layer/encapsulant layer interface 23 and towards the silicon layer 14 in the case of the encapsulant layer/silicon layer interface 25 to form a bubble 29. The expansion of gas may continue to occur after the application of the pulsed laser beam 18 has concluded, therefore the illustration of FIG. 8 may be representative of a period after the scanning 103 has been completed. The bubbles 29 may improve the ease of the separating 104 of the glass layer 12 and/or the silicon layer 14 from the encapsulant layer 16 due to the bubbles 29 applying a separating force at one or both of the interfaces 23, 25. In other embodiments, the bubbles 29 may expand such that two or more of the bubbles 29 join to form a single, larger bubble, which may further improve the ease of the separating 104 of the glass layer 12 and/or the silicon layer 14 from the encapsulant layer 16.

The pulsed laser beam 18 is generated by a pulsed laser 32, such as a picosecond or femtosecond-type laser. In other embodiments, a plurality of pulsed lasers 32 may be provided and may be applied 102 through the glass layer 12 simultaneously in order to reduce the overall time taken to complete the method 100 and to increase manufacturing efficiency and throughput.

It will be understood that the pulsed laser 32 may scan the pulsed laser beam 18 across the glass layer 12 using various methods. For example, the pulsed laser 32 may comprise one or more of the following components not illustrated in the drawings: a light source, a collimator to form a collimated beam from the light source, a rotating polygon mirror to reflect the collimated beam, and a lens, such as an F-theta lens, to focus the reflected beam onto a target. The rotation of the polygon mirror allows the pulsed laser beam to move or scan along a particular focal plane, for example, the sandwich structure 20. As another example, the pulsed laser 32 may be in the form of a galvanometer scanner including one or more rotatable mirrors to deflect a pulsed laser beam from a light source.

It will be understood that the scanning 103 the pulsed laser beam 18 along the glass layer 12 is not required for performing the method 100 of delaminating the photovoltaic module 10. For example, the pulsed laser beam 18 may be applied at a single discrete portion 26 on the glass layer 12 to degenerate the encapsulant layer 16 at the interfaces 23, 25 below the single discrete portion 26, which may be sufficient for the separating 104 at least one of the glass layer 12 and the silicon layer 14 from the encapsulant layer 16 of the photovoltaic module 10.

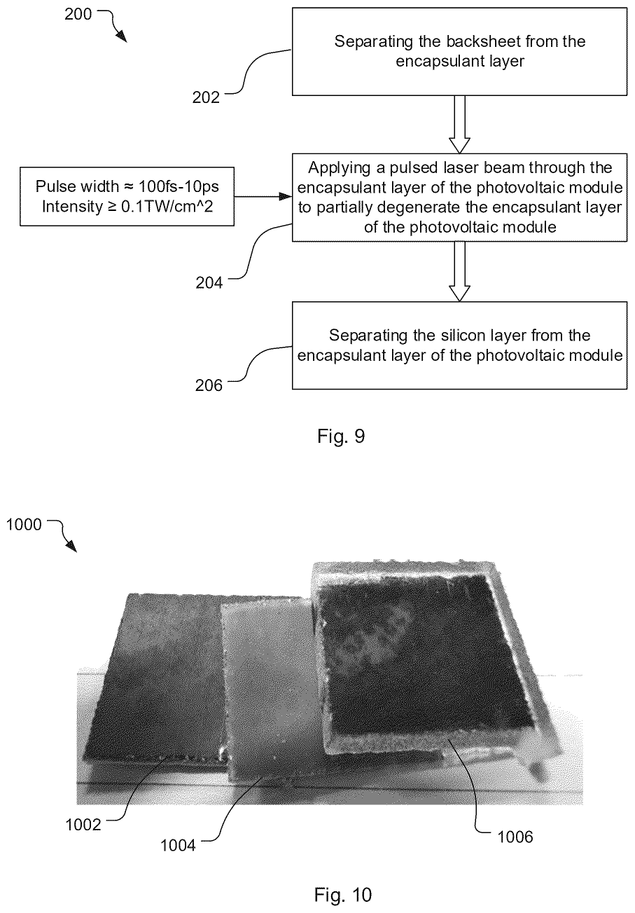

In another embodiment, the photovoltaic module 10 may have a non-transparent backsheet (not shown) attached to the silicon layer 14 by the encapsulant layer 16 disposed between the backsheet and the silicon layer 16, for example, as a part of a monofacial photovoltaic module having a front-facing glass surface. A method 200 for delaminating this type of photovoltaic module 10 according to an embodiment of the present disclosure is shown in FIG. 9. The method 200 comprises separating 202 the backsheet from the encapsulant layer 16 using, for example, a mechanical process such as peeling. The method 200 further comprises applying 204 the pulsed laser beam 18, e.g. having the same pulse width and intensity range of the pulsed laser beam 18 used in the method 100 described above, through the encapsulant layer 16 of the photovoltaic module 10 to at least partially degenerate the encapsulant layer 16 of the photovoltaic module 10 such that the encapsulant layer 16 is at least partially degenerated by the pulsed laser beam 18 without substantially increasing a resting temperature of the encapsulant layer 16. The method 200 further includes separating 206 the silicon layer 14 from the encapsulant layer 16 of the photovoltaic module 10. The method 200 may be applied as a standalone method or may be applied before or after applying the method 100. For example, the method 100 may be applied to an operatively front facing portion of a photovoltaic module 10 and the method 200 may be applied to an operatively rear facing portion of the same photovoltaic module 10. It will be understood that various embodiments of the method 200 may include any relevant features of the method 100 described above.

The method 100, 200 according to one or more embodiments of the present disclosure may allow for the delamination of the photovoltaic module 10 while maintaining at least one of the glass layer and the silicon layer 14 as a whole layer or a large portion of material, which may increase the profitability of recycling the photovoltaic module 10 compared to recovering glass and/or silicon in shredded form. This increase in profitability may also increases the viability of the method 100, 200, thereby also increasing the prevalence of photovoltaic modules being recycled or reused.

The degenerating of at least part of the encapsulant layer 16 without substantially increasing the resting temperature of the encapsulant layer 16, for example, by performing a non-thermal process such as cold ablation, may greatly reduce the likelihood of damaging the glass layer 12 and/or the silicon layer 14 during the applying 102, 204 the pulsed laser beam 18 compared to thermal processes of degenerating or removing encapsulant material. This may provide recovered glass and/or silicon material with improved viability for reuse and facilitate the recovery of the glass layer 12 and/or the silicon layer 14 as undamaged whole layers or large portions.

The method 100, 200 according to one or more embodiments of the present disclosure may also be less complex, may require less equipment, and may allow for delamination of the photovoltaic module 10 to be completed in a shorter time frame compared to thermal recycling processes. For example, performing the method 100, 200 according to one or more embodiments of the present disclosure on a photovoltaic module with a surface area of 2 metres squared requires a period of between about 30 seconds and about 10 minutes, depending on the operating parameters selected or which of the embodiments of the method 100, 200 is being performed. Also, the economic viability of the method 100, 200 according to one or more embodiments of the present disclosure may not be dependent on the volume of photovoltaic modules being recycled, thereby incentivising the method 100, 200 to be performed by both smaller and larger companies, which increases the amount of reusing and recycling of photovoltaic modules. It will be understood that the method 100, 200 according to one or more embodiments of the present disclosure may require a shorter or longer period of time to delaminate a photovoltaic module with a surface area of 2 metres squared in some embodiments.

The method 100, 200 according to one or more embodiments of the present disclosure may also be environmentally friendly as chemicals may be not required to perform the applying 102 the pulsed laser beam 18 or the separating 104, 206 at least one of the glass layer 12 and the silicon layer 14 from the encapsulant layer 16, nor does the method 100, 200 produce any harmful by-products. The method 100, 200 according to one or more embodiments of the present disclosure may also be efficient, due to only requiring the applying 102, 204 the pulsed laser beam 18 to be performed on one side of the photovoltaic module 10 and/or due to the method 100, 200 being applicable to photovoltaic modules of any size since the applying 102, 204 of the pulsed laser beam 18 may be performed without enclosed equipment specific to a particular photovoltaic module size. The method 100 according to one or more embodiments of the present disclosure may also be versatile as it may be able to be performed without requiring the removal of the glass layer 12 or the backsheet in the embodiment of the method 100 applied through the glass backsheet.

The embodiment of the method 100, 200 discussed above with respect to FIGS. 3-6 may further increase the efficiency of the method 100, 200 by targeting only portions 22, 24 of the encapsulant layer interfacing with, and therefore bonding with, the glass and/or silicon layer 12, 14 instead of the bulk of the encapsulant material. Further, this targeted approach may reduce the probability of inadvertent photothermal ablation increasing the temperature of, and thereby damaging, the glass and/or silicon layer 12, 14. The simultaneous degeneration of the one or more portions 22 with the one or more portions 24 of the encapsulant layer 16 may further increase the efficiency of the method 100, 200 by decreasing the total time required to perform the method 100, 200.

The embodiment of the method 100, 200 including the scanning 103 the pulsed laser beam 18 may allow for larger photovoltaic modules to be delaminated by the method 100, 200 as the pulsed laser beam 18 is configurable to be scanned along a photovoltaic surface of any size. The scanning 103 may also provide versatility by allowing the scan path to be configured to increase the proportion of overlapping discrete portions 26 to degenerate more of the encapsulant layer 16 for ease of the separating 104, or to decrease the proportion of overlapping discrete portions 32 or provide spaced discrete portions 26 in order to increase processing efficiency and throughput.

The method 100, 200 may allow for the reduction or minimisation or elimination of thermal processes also due to the ability of the pulsed laser beam 18 to have a fluence range high enough to allow for a consistent laser application, and also low enough not to increase the temperature of the bulk of the encapsulant layer 16 which in turn may increase the temperature of the glass layer 12 and/or the silicon layer 14. The fluence range of the pulsed laser beam 18 is able to be reduced as the cold ablation process is dependent on pulse width and intensity as opposed to fluence as in photothermal processes.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

### EXAMPLES

The following examples are to be understood as illustrative only. The following examples should therefore not be construed as limiting the embodiments of the disclosure in any way.

One 1.5 cm×1.5 cm square photovoltaic sandwich structure 1001 including a silicon layer 1002, an encapsulant layer 1004 in the form of POE, and a glass backsheet 1006 was prepared and subjected to a pulsed laser beam to examine the effect of cold ablation. The preparation of the sandwich structures involved fracturing a larger 20 cm×20 cm sandwich structure module using a water jet cutter, which resulted in a periphery of the glass backsheet 1006 being rough. The laser was mounted above a substrate and the sandwich structure 1001 was placed onto the substrate with the glass backsheet 1006 facing the laser for the applying of the pulsed laser beam through the glass backsheet 1006. The pulsed laser beam was scanned across multiple discrete portions of the glass backsheet 1006 following a path along a series of parallel spaced lines. Each discrete portion at which the pulsed laser beam passed through the glass backsheet 1006 overlapped about 50% of another discrete portion on the same line and overlapped about 50% of a further discrete portion on an adjacent line. The diameter of the pulsed laser beam was 25 microns.

The make and model of the laser was Coherent® Super Rapid-HE and the pulsed laser beam had a wavelength of 532 nanometres, a pulse width of 10 picoseconds, a power of 0.8 watts, a pulse repetition rate of 200 kilohertz, and a deactivation time of 5 microseconds. The fluence of the pulsed laser beam was 6 joules per square centimetre and the intensity of the pulsed laser beam was 0.6 terawatts per square centimetre. FIG. 10 shows a photograph 1000 of the silicon layer 1002, the encapsulant layer 1004 and the glass backsheet 1006 separated as whole layers using a knife following the application of the pulsed laser beam. Each of the layers 1002, 1004, 1006 were substantially undamaged and were cold to the touch following the experiment, indicating that cold ablation had successfully occurred. The knife was used to separate only a periphery of the backsheet from the encapsulant layer as the vast majority of the encapsulant layer within the periphery had been degenerated. The reason for the periphery of the encapsulant later not becoming degenerated is due to the roughened periphery of the glass layer which scattered the pulsed laser beam such that the intensity of the pulsed laser beam reaching the periphery of the encapsulant layer was not high enough to allow for cold ablation to occur. Commercially available photovoltaic modules do not have glass backsheets with roughened edges as did the sandwich structure in this example, therefore it is expected that the knife will not be necessary to use to separate the glass backsheet from the encapsulant layer of commercially available photovoltaic modules.

In another example, two 1.5 cm×1.5 cm square photovoltaic sandwich structures 1101a, 1101b each including a front glass layer 1102, a first encapsulant layer 1104 in the form of POE, a silicon layer 1106, a second encapsulant layer 1108, and a glass backsheet 1110 were prepared. The front glass layer 1102 and the glass backsheet 1110 of each sandwich structure were each subjected to a pulsed laser beam to examine the effects of increasing the intensity of the pulsed laser beam. The preparation of the sandwich structures involved fracturing a larger sandwich structure module, which resulted in a roughened periphery of the front glass layer 1102 and the glass backsheet 1110.

The operating parameters of the pulsed laser beam were the same as for the previous example, except for the fluence and intensity values, which were varied for each of the sandwich structures as shown in Table 1 below. Since the pulse width able to be produced by the laser was fixed, the intensity of the pulsed laser beam was unable to be increased without increasing the fluence of the pulsed laser beam, however, it is understood that the fluence ranges used below would not be high enough to significantly affect the encapsulant degeneration results.

TABLE 1
Fluence and intensity of the pulsed laser beam
applied to the sandwich structure samples.

| Sandwich structure number | Fluence (J/cm²) | Intensity (TW/cm²) |
|---|---|---|
| 1 | 6 | 0.6 |
| 2 | 8 | 0.8 |

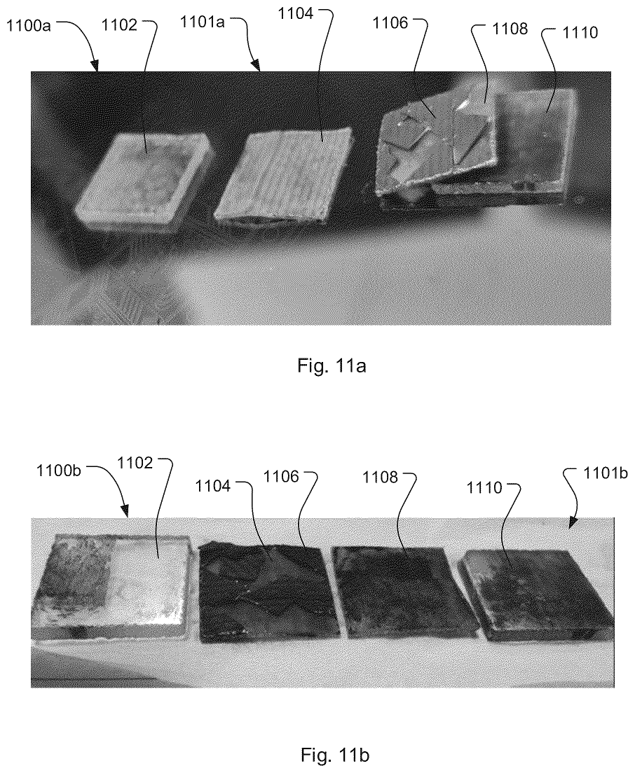

A shown in photographs 1100a and 1100b of FIGS. 11a and 11b, respectively, the layers 1102, 1104, 1106, 1108, 1110 were separated using a knife to remove any residual encapsulant material that was not degenerated after the application of the puled laser beam on both sides of each sandwich structure, i.e. applying the pulsed laser beam through the front glass layer 1102 and through the glass backsheet layer 1110. Due to the roughened periphery of the of the front glass layer 1102 and the glass backsheet 1110, the pulsed laser beam was scattered such that the intensity of the pulsed laser beam reaching the periphery of the encapsulant layer was not high enough to allow for cold ablation of the encapsulant layers 1104, 1108 proximate the periphery of the front glass layer 1102 and the glass backsheet layer 1110 to occur. This caused portions of the encapsulant layers 1104, 1108 to not degenerate, thereby not allowing the silicon layer 1106 to be separated as a whole layer due to the silicon layer 1106 cracking under the pressure of the knife during separation. Recovering large portions of the silicon layer 1106 is still a desirable outcome as opposed to only being able to recover silicon in shredded form. It is expected that for commercial photovoltaic modules without roughened glass peripheries, the entire silicon layer will be recoverable and a knife will not be required to separate the layers 1102, 1104, 1106, 1108, 1110 due to a greater proportion of the encapsulant material being degenerated.

Each sandwich structure 1101a, 1101b felt cold to the touch of a human hand immediately following the laser beam being applied to each sandwich structure 1101a, 1101b, and the front glass layer 1102 and glass backsheet 1104 were separated as whole layers, indicating that cold ablation of the encapsulant layers 1104, 1108 took place at the majority of the glass layer/encapsulant layer and encapsulant layer/silicon layer interfaces since the resting temperature of the encapsulant layer did not substantially increase.

In another example, various parameters of the pulsed laser beam were applied to one side of a glass-glass photovoltaic sandwich structure 1202. The sandwich structure 1202 included a front glass layer 1204 attached to a silicon layer 1206 by a first encapsulant layer 1208, in the form of POE, disposed between the front glass layer 1204 and the silicon layer 1206, and a glass backsheet layer 1210 attached to the silicon layer 1206 by a second encapsulant layer 1212, in the form of POE, disposed between the glass backsheet layer 1210 and the silicon layer 1206. The pulsed laser beam was applied to three 1.5 mm×1.5 mm square portions 1214, 1216, 1218 of the front glass layer 1204 with fluence and intensity values as shown in Table 2 below. All other operating parameters were in line with the previous examples.

TABLE 2
Fluence and intensity of the pulsed laser beam applied
to the square portions of the sandwich structure.

| Square portion reference | Fluence (J/cm²) | Intensity (TW/cm²) |
|---|---|---|
| 1214 | 3.3 | 0.33 |
| 1216 | 6 | 0.6 |
| 1218 | 8 | 0.8 |

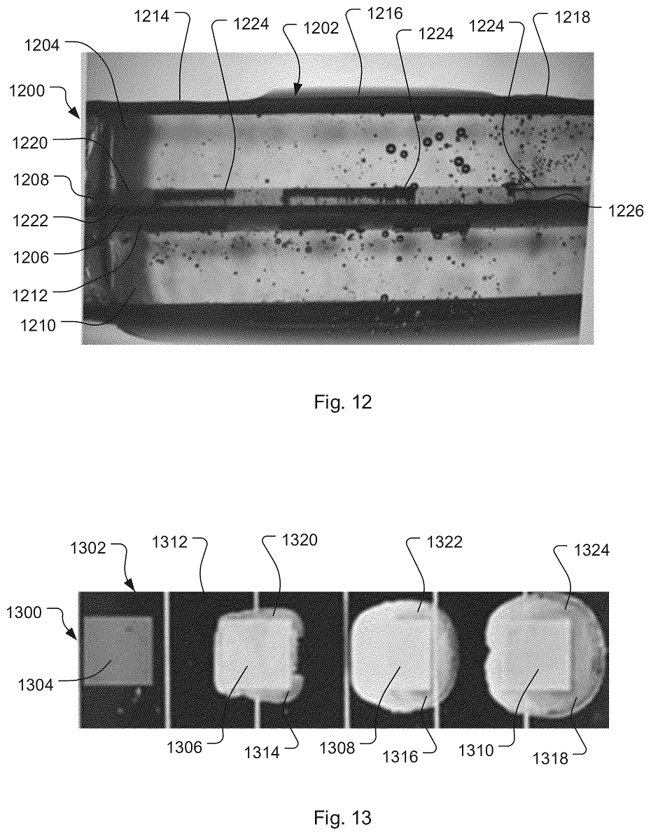

FIG. 12 shows a cross section photograph 1200 of the sandwich structure 1202, which was examined under a microscope to observe the encapsulant degeneration following the application of the pulsed laser beam. It was observed in the cross-section photograph 1200 that encapsulant degeneration occurred at the glass layer/encapsulant layer interface 1220 and the encapsulant layer/silicon layer interface 1222 between the front glass layer 1204 and the silicon layer 1206. In particular, the cross-section photograph 1200 shows the degeneration of one or more portions 1224, 1226 of each of the respective interfaces 1220, 1222 following the application of the pulsed laser beam. This indicates that the pulsed laser beam applications through the front glass layer 1204 targeted the first encapsulant layer 1208 at the respective interfaces 1220, 1222 which may decrease the likelihood of increasing the temperature of the first encapsulant layer 1208 and damaging the front glass, glass backsheet or silicon layers 1204, 1210, 1206 and may be a more efficient process compared to degenerating the bulk of the encapsulant material. A portion of the bulk of the encapsulant layer 1208 was also degenerated by the pulsed laser beam being applied to the portions 1214 and 1216 of the front glass layer 1204. The pulsed laser beam being applied to the portion 1218 of the front glass layer 1204 caused degeneration substantively only at the interfaces 1220, 1222 rather than the bulk of the encapsulant layer, indicating an efficient degeneration of the encapsulant layer 1208. Even though some degeneration of the bulk of the first encapsulant layer 1208 occurred, it will be understood that the encapsulant material proximate the interfaces 1220, 1222 was substantially targeted by the applications of the pulsed laser beam. The pulsed laser beam was also applied to the glass backsheet layer 1210 and, due to the symmetrical nature of the sandwich structure 1202, the effect on the second encapsulant layer 1212 proximate the glass backsheet layer 1210 was similar to the effect on the first encapsulant layer 1208 proximate the front glass layer 1204 when the pulsed laser beam was applied to the front glass layer 1204 as described above.

In another example, a pulsed laser beam was applied to a commercial photovoltaic module 1302 at four spaced square portions 1304, 1306, 1308, 1310, each being 1.5 mm×1.5 mm in size. The photovoltaic module 1302 comprised a front glass layer 1312, an encapsulant layer (not shown) formed from EVA, and a silicon layer (not shown). The photovoltaic module 1302 was left to rest for 2 days after the application of the pulsed laser beam to investigate the formation of gas bubbles at the encapsulant layer/silicon layer interface underneath a front glass layer 1312 of the photovoltaic module 1302. The fluence and intensity of the pulsed laser beam was varied for each of the four square portions 1304, 1306, 1308, 1310 as shown at Table 3 below. All other operating parameters were in line with the previous examples.

TABLE 3
Fluence and intensity of the pulsed laser beam applied
to the square portions of the photovoltaic module.

| Square portion reference | Fluence (J/cm²) | Intensity (TW/cm²) |
|---|---|---|
| 1304 | 1.6 | 0.16 |
| 1306 | 3.3 | 0.33 |
| 1308 | 6 | 0.6 |
| 1310 | 8 | 0.8 |

As shown in photograph 1300 of FIG. 13, the photovoltaic module 1302 was captured 2 days after the application of the pulsed laser beam. The first square portion 1304 showed no significant changes, the second square portion 1306 included a bubble 1314 formed at the encapsulant layer/silicon layer interface, the third square portion 1308 included a bubble 1316 formed at the encapsulant layer/silicon layer interface, and the fourth square portion 1310 included a bubble 1318 formed at the encapsulant layer/silicon layer interface. The bubble 1318 was larger than the bubble 1316, and the bubble 1316 was larger than the bubble 1314, indicating that increasing the intensity of the pulsed laser beam caused a larger bubble to form. The bubbles 1314, 1316, 1318 formed due to expanding gas generated in response to a portion of the encapsulant material degenerating due to the application of the pulsed laser beam. The bubbles 1314, 1316, 1318 caused respective portions 1320, 1322, 1324 of the encapsulant material that had not been degenerated by the cold ablation process to separate from the silicon layer of the photovoltaic module 1302 due to pressure applied by the expanding gas.

1. A method of delaminating a photovoltaic module, the photovoltaic module having a glass layer attached to a silicon layer by an encapsulant layer disposed between the glass layer and the silicon layer, the method comprising:
applying a pulsed laser beam through the glass layer of the photovoltaic module to at least partially degenerate the encapsulant layer of the photovoltaic module, the pulsed laser beam having a pulse width and an intensity, wherein the pulse width is selected to be between about 100 femtoseconds and about 10 picoseconds, and the intensity is selected to be greater than 0.1 terawatts per square centimetre, such that the encapsulant layer is at least partially degenerated by the pulsed laser beam without substantially increasing a resting temperature of the encapsulant layer; and
separating at least one of the glass layer and the silicon layer from the encapsulant layer of the photovoltaic module.

2. The method of claim 1, wherein the applying of the pulsed laser beam degenerates substantially only one or more portions of the encapsulant layer that are proximate the glass layer and/or one or more portions of the encapsulant layer that are proximate the silicon layer.

3. The method of claim 1, wherein the applying of the pulsed laser beam degenerates one or more portions of the encapsulant layer that are proximate the glass layer simultaneously with one or more portions of the encapsulant layer that are proximate the silicon layer.

4. The method of claim 1, wherein the glass layer comprises an operatively front facing glass layer, and wherein the applying the pulsed laser beam through the glass layer comprises applying the pulsed laser beam through the operatively front facing glass layer.

5. The method of claim 1, wherein the glass layer comprises a glass backsheet, and wherein the applying the pulsed laser beam through the glass layer comprises applying the pulsed laser beam through the glass backsheet.

6. The method of claim 1, further comprising scanning the pulsed laser beam across the glass layer.

7. The method of claim 6, wherein the scanning the pulsed laser beam comprises scanning the pulsed laser beam along a path comprising a series of spaced, substantially straight lines.

8. The method of claim 6, wherein the scanning the pulsed laser beam comprises applying pulses of the pulsed laser beam through discrete portions of the glass layer such that each discrete portion overlaps between about 10% and about 90% of at least one other discrete portion.

9. The method of claim 1, wherein the separating at least one of the glass layer and the silicon layer from the encapsulant layer comprises separating at least one of the glass layer and the silicon layer as a single piece of material.

10. The method of claim 1, wherein the separating at least one of the glass layer and the silicon layer from the encapsulant layer comprises peeling the encapsulant layer away from at least one of the glass layer and the silicon layer.

11. The method of claim 1, wherein the separating at least one of the glass layer and the silicon layer from the encapsulant layer comprises separating both the glass layer and the silicon layer from the encapsulant layer.

12. The method of claim 1, a wavelength of the pulsed laser beam is selected to be between about 300 nanometres and about 1100 nanometres.

13. The method of claim 1, wherein a fluence of the pulsed laser beam is selected to be between about 1 joule per square centimetre and about 10 joules per square centimetre.

14. The method of claim 1, wherein the intensity of the pulsed laser beam is selected to be between about 0.1 terawatts per square centimetre and about 50 terawatts per square centimetre.

15. The method of claim 1, wherein a deactivation period of the pulsed laser beam between pulses is selected to be between about 1 millisecond and about 10 milliseconds.

16. The method of claim 1, wherein a power of the pulsed laser beam is selected to be between about 50 watts and about 3000 watts.

17. A method of delaminating a photovoltaic module, the photovoltaic module having a backsheet attached to a silicon layer by an encapsulant layer disposed between the backsheet and the silicon layer, the method comprising:
separating the backsheet from the encapsulant layer;
applying a pulsed laser beam through the encapsulant layer of the photovoltaic module to at least partially degenerate the encapsulant layer of the photovoltaic module, the pulsed laser beam having a pulse width and an intensity, wherein the pulse width is selected to be between about 100 femtoseconds and about 10 picoseconds, and the intensity is selected to be greater than 0.1 terawatts per square centimetre, such that the encapsulant layer is at least partially degenerated by the pulsed laser beam without substantially increasing a resting temperature of the encapsulant layer; and
separating the silicon layer from the encapsulant layer of the photovoltaic module.
